(19) United States
(12) Patent Application Publication
(10) Pub. No.: US 2025/0227982 A1
(43) Pub. Date: Jul. 10, 2025

(54) SEMICONDUCTOR DEVICE, METHOD FOR MANUFACTURING SEMICONDUCTOR DEVICE, AND POWER CONVERSION DEVICE

(71) Applicant: Minebea Power Semiconductor Device Inc., Ibaraki (JP)

(72) Inventor: Masaki SHIRAISHI, Hitachi-shi (JP)

(21) Appl. No.: 18/850,377

(22) PCT Filed: Dec. 9, 2022
(86) PCT No.: PCT/JP2022/045440

§ 371 Date: Sep. 24, 2024

(30) Foreign Application Priority Data
Mar. 28, 2022 (JP) 2022-051438

(51) Int. Cl. H10D 84/01; H10D 12/00; H10D 84/00

(52) U.S. Cl. CPC H10D 84/0109; H10D 12/481; H10D 84/161

(57) ABSTRACT

Provided are a semiconductor device, a method for manufacturing the semiconductor device, and a power conversion device for allowing the low injection of the diode unit by forming the Schottky barrier diode in the diode unit of the RC-IGBT through a process simpler than the usual process. A semiconductor device (RC-IGBT) is formed as an RC-IGBT having an IGBT unit and a diode unit formed in a single chip. The diode unit includes a plurality of first trenches connected to a gate potential or an emitter potential in the absence of a body layer of second conductive type, and a second trench which is formed between two of the first trenches, and connected to the emitter potential. A Schottky barrier diode is provided, which is constituted by the second trench and a drift layer of a first conductive type in contact with a side wall of the second trench.

### TECHNICAL FIELD

The present invention relates to a semiconductor device, a method for manufacturing the semiconductor device, and a power conversion device.

### BACKGROUND ART

A reverse conducting IGBT (hereinafter referred to as “RC-IGBT”) formed by incorporating an IGBT (Insulated Gate Bipolar Transistor) and a diode in the same chip provides advantages: (1) reduction in the chip size by making each termination region of the IGBT and the diode commonized; and (2) reduction in thermal resistance by dissipating the loss generated either in the IGBT region or the diode region from the entire chip. Meanwhile, as the IGBT and the diode are fabricated in the same chip, it is difficult to attain simultaneous optimization among the respective chips. Especially, it is difficult to execute the life-time control of the diode unit, which demands the low injection of the diode, and reduction in the recovery loss.

Patent Literature 1 discloses the semiconductor device as a means for the low injection of the diode unit of the RC-IGBT, for example. Specifically, the semiconductor device includes a plurality of n-type pillar regions 24 that are Schottky connected to an anode electrode 14. In Patent Literature 1, the pillar regions 24 Schottky connected to the upper electrode 14 form the Schottky barrier diode (hereinafter referred to as SBD) to attain suppression of hole injection of the pn diode.

### CITATION LIST

### Patent Literature

Patent Literature 1: Japanese Unexamined Patent Application Publication No. 2015-165541

### SUMMARY OF INVENTION

### Technical Problem

As disclosed in Patent Literature 1, the diode unit of the RC-IGBT is provided with the n-pillar layer for forming the Schottky barrier diode. In order to form the pillar layer, it is necessary to execute the photolithography process and implant process for forming the n-pillar layer in addition to the conventional process for forming the diode unit of the RC-IGBT, resulting in the complicated process.

In light of the above circumstances, it is an object of the present invention to provide the semiconductor device, the method for manufacturing the semiconductor device, and the power conversion device for allowing the low injection of the diode unit by forming the Schottky barrier diode in the diode unit of the RC-IGBT through the process simpler than the usual process.

### Solution to Problem

In an aspect of the present invention for attaining the above-described object, the semiconductor device is formed as an RC-IGBT having an IGBT unit and a diode unit formed in a single chip. The diode unit includes a plurality of first trenches connected to a gate potential or an emitter potential in the absence of a body layer of second conductive type, and a second trench which is formed between two of the first trenches, and connected to the emitter potential. A Schottky barrier diode is provided, which is constituted by the second trench and a drift layer of first conductive type in contact with a side wall of the second trench.

According to another aspect of the present invention to solve the above-described problem, a power conversion device includes a pair of DC terminals, AC terminals, the number of which is the same as the number of phases of an AC output, switching legs that are connected between the pair of DC terminals, the number of which is the same as the number of phases of the AC output, and connected in series to two parallel circuits each formed of a switching element and a diode connected reversely in parallel to the switching element, and a gate circuit for controlling the switching element. The diode and the switching element constitute the above-described semiconductor device.

The specific structure of the present invention is described in claims.

### Advantageous Effects of Invention

The present invention provides the semiconductor device, and the power conversion device for e, the method for manufacturing the allowing the low injection of the diode unit by forming the Schottky barrier diode in the diode unit of the RC-IGBT through the process simpler than the usual process.

Other problems, structures, and advantageous effects will be clarified by explanations of an embodiment as described below.

### BRIEF DESCRIPTION OF DRAWINGS

FIG. 1 is a sectional view schematically showing an example of a semiconductor device according to the present invention.

FIG. 2(a) is a sectional view schematically showing a process step of a method for manufacturing the semiconductor device according to the present invention.

FIG. 2(b) is a sectional view schematically showing a process step of a method for manufacturing the semiconductor device according to the present invention.

FIG. 2(c) is a sectional view schematically showing a process step of a method for manufacturing the semiconductor device according to the present invention.

FIG. 2(d) is a sectional view schematically showing a process step of a method for manufacturing the semiconductor device according to the present invention.

FIG. 2(e) is a sectional view schematically showing a process step of a method for manufacturing the semiconductor device according to the present invention.

FIG. 3 is a circuit diagram schematically showing an example of a power conversion device according to the present invention.

### DESCRIPTION OF EMBODIMENTS

The present invention is described in detail with reference to the drawings.

### [Semiconductor Device]

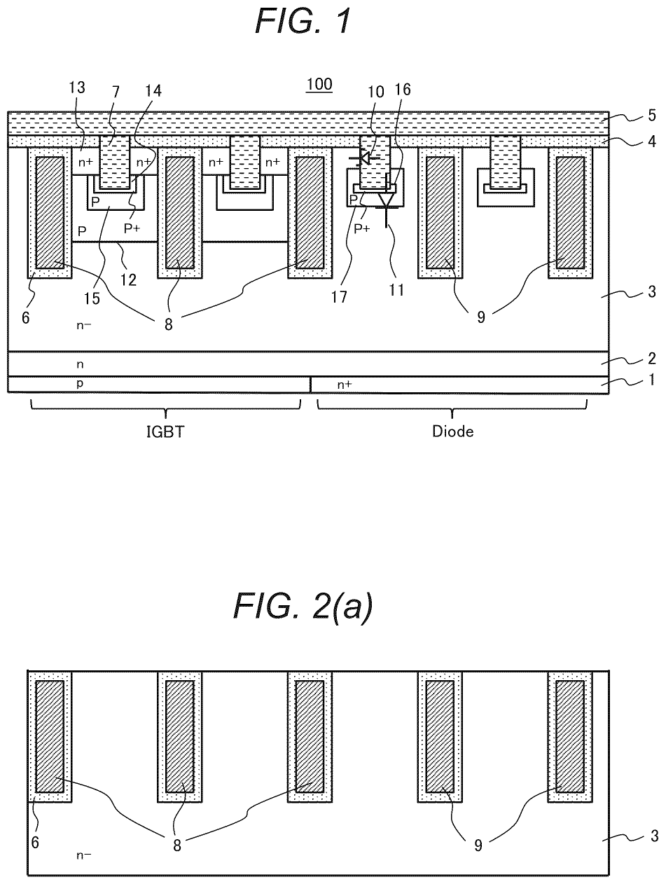

FIG. 1 is a sectional view schematically showing an example of a semiconductor device according to the present invention. As FIG. 1 shows, a semiconductor device 100 according to the present invention includes an IGBT unit and a diode unit. The semiconductor device is structured by stacking a diffusion layer 1 connected to a collector electrode layer/cathode electrode layer (not shown), buffer layer 2, n-drift layer 3, p body layer 12 formed in the IGBT unit, an insulating layer 4, and emitter electrode/anode electrode 5 from a back surface side to the front surface side. The conductive type “p” and conductive type “n” as shown in FIG. 1 may be inverted.

The IGBT unit includes the p body layer 12 and an n⁺ layer 13, which intervene between two trenches 8. The trench 8 is connected to a gate electrode (not shown). Meanwhile, the diode unit includes trenches (first trenches) 9 but does not include the p body layer and the n⁺ layer. Both the IGBT unit and the diode unit include Si etch regions 7, and p⁺ layers (first semiconductor layers) 14, 16 and p layers (second semiconductor layers) 15, 17, which are formed below the Si etch regions 7, respectively.

The IGBT unit includes an ohmic contact formed by a side wall of the Si etch region 7 and the n⁺ layer, and has the p body layer 12 connected to the emitter electrode 5 via the p layer 15 and the p⁺ layer 14. Each side wall of the Si etch region 7 (second trench) formed in the diode unit is in contact with an n drift layer (n′ layer) to form the Schottky junction. The p⁺ layer 16 and the p layer 17, which are formed below the Si etch region constitute a pn diode.

The p layers 15, 17 are formed by ion implantation through the corresponding Si etch regions 7. The n drift layer (n-layer) 3 remains between the p layer 17 and the second trench 7 to secure the current path of the Schottky barrier diode 10. The pressure resistance may be held by depletion of the n drift layer (n-layer) between the second trench 7 and the p layer 17 as the current path as a result of lateral extension of the depletion layer from the trench connected to the gate or the anode.

### [Method for Manufacturing Semiconductor Device]

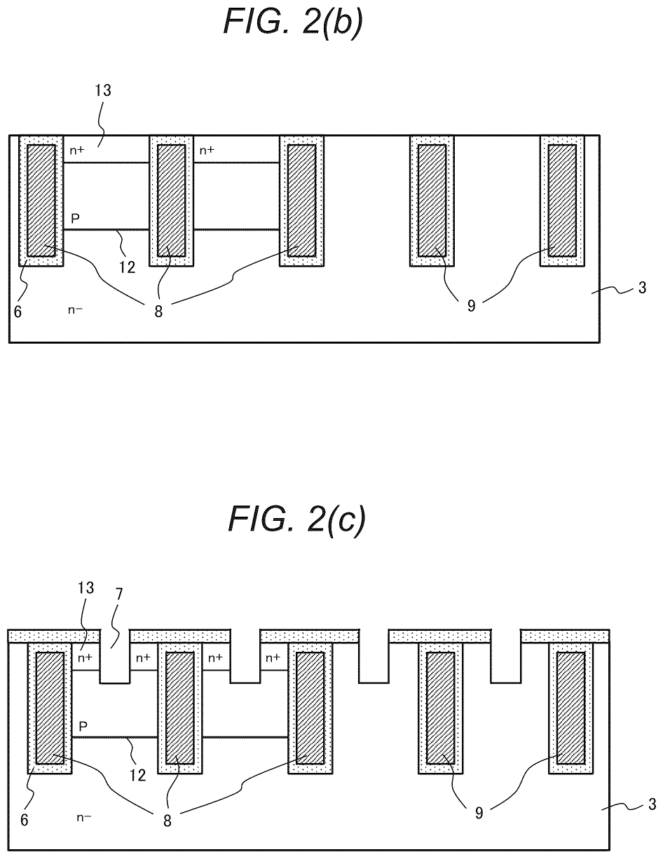

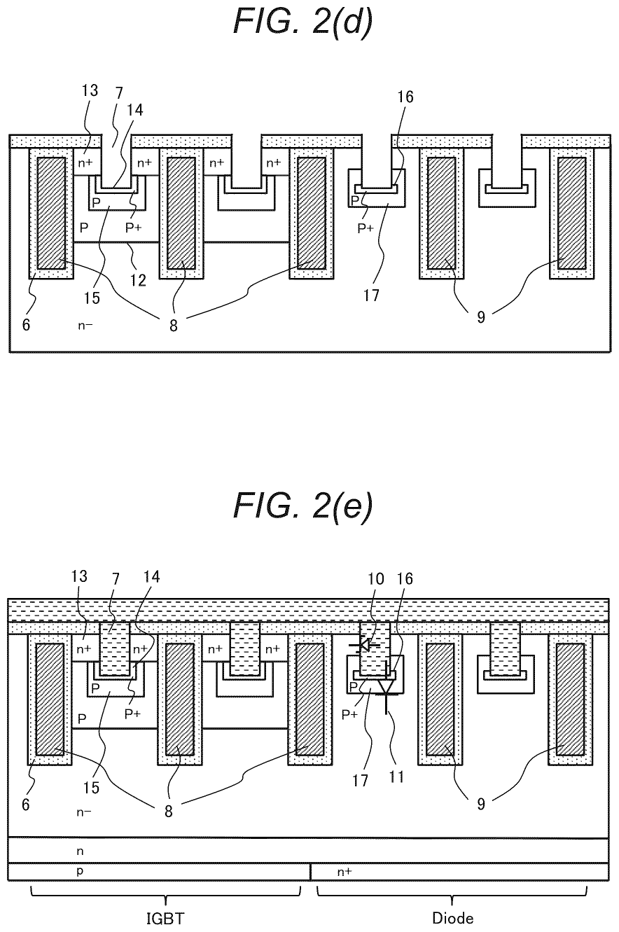

The semiconductor device according to the present invention is described. FIGS. 2(a) to 2(e) are sectional views schematically showing a process step of a method for manufacturing the semiconductor device according to the present invention. The method for manufacturing the semiconductor device according to the present invention is described with reference to FIGS. 2(a) to 2(e).

Referring to FIG. 2(a), firstly, the trenches 8, 9 each embedded with a polysilicon electrode via an oxide film 6 are formed in the n drift layers 3 of the IGBT unit and the diode unit.

Referring to FIG. 2(b), the p body layer 12 and the n⁺ layer 13 are formed only in the IGBT unit by the ion implantation and thermal diffusion.

Referring to FIG. 2(c), the Si etch regions 7 are formed in the IGBT unit and the diode unit.

Referring to FIG. 2(d), the p⁺ layers 14, 16, and the p layers 15, 17 are formed in the IGBT unit and the diode unit by the ion implantation and thermal diffusion through the Si etch regions 7, respectively.

Referring to FIG. 2(e), finally, the emitter electrode/anode electrode 5 is formed on the front surface, and the n buffer layer 2 is formed on the back surface. The p layer and the n⁺ layer are formed each as the diffusion layer 1 in the IGBT unit and the diode unit, respectively.

The above-described method for manufacturing the semiconductor device according to the present invention attains manufacturing of the structure that allows the low injection of the Daiode unit without requiring the photolithography process and the implant process.

### [Power Conversion Device]

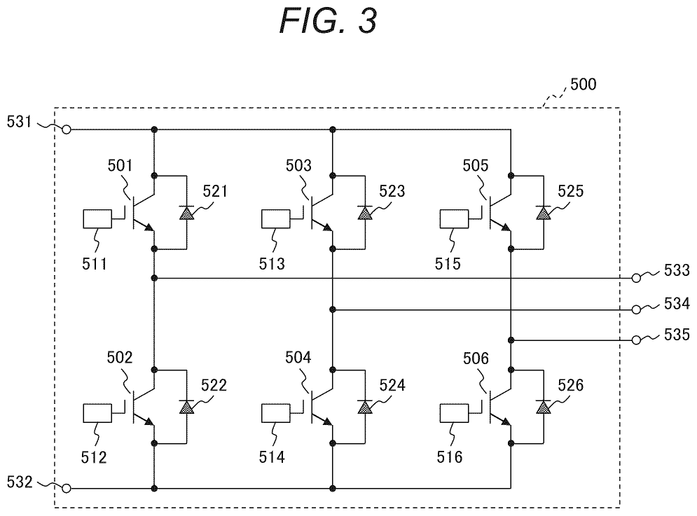

FIG. 3 is a circuit diagram schematically showing a structure of an example of the power conversion device according to the present invention. FIG. 3 shows an example of a circuit structure of a power conversion device 500 of an embodiment, and a connection relation between a DC power supply and a three-phase AC motor (AC load).

The power conversion device 500 of the embodiment employs the semiconductor devices according to the present invention as elements 501 to 506, and 521 to 526.

As FIG. 3 shows, the power conversion device 500 of the embodiment includes a pair of DC terminals constituted by a P terminal 531 and an N terminal 532, and a U terminal 533, a V terminal 534, and a W terminal 535 as AC terminals, the number of which is the same as the number of AC output phases.

The power conversion device includes a switching leg formed of a pair of power switching elements 501 and 502 connected in series, and makes the U terminal 533 connected to a series connected point of those elements serving as an output. The power conversion device further includes a similarly structured switching leg formed of a pair of power switching elements 503 and 504 connected in series, and makes the V terminal 534 connected to a series connected point of those elements serving as an output. The power conversion device further includes a similarly structured switching leg formed of a pair of power switching elements 505 and 506 connected in series, and makes the W terminal 535 connected to a series connected point of those elements serving as an output.

The three-phase switching legs which are formed of the power switching elements 501 to 506, respectively are connected between the DC terminals of the P terminal 531 and the N terminal 532 so that DC power is supplied from a not shown DC power supply. The three-phase AC terminals including the U terminal 533, the V terminal 534, and the W terminal 535 of the power conversion device 500 are connected to a not shown three-phase AC motor while serving as a three-phase AC power supply.

The power switching elements 501 to 506 are connected reversely in parallel to the diodes 521 to 526, respectively. Input terminals of the respective gates of the power switching elements 501 to 506 each formed of the IGBT, for example, are connected to gate circuits 511 to 516 correspondingly so that the power switching elements 501 to 506 are controlled by the gate circuits 511 to 516, respectively. The gate circuits 511 to 516 are integrally controlled by an integrated control circuit (not shown).

The gate circuits 511 to 516 execute integral control of the power switching elements 501 to 506 appropriately so that the DC power of a DC power supply Vcc is converted into the three-phase AC power, and the converted power is output from the U terminal 533, the V terminal 534, and the W terminal 535.

Application of the semiconductor device (RC-IGBT) according to the present invention to the power conversion device 500 allows integration of the power switching elements 501 to 506, and the diodes 521 to 526 into a single structure, resulting in size reduction of the device. As described above, the use of the semiconductor device according to the present invention allows provision of the power conversion device which improves the recovery characteristic of the diode unit.

The present invention shows that it is possible to provide the semiconductor device, the method for manufacturing the semiconductor device, and the power conversion device for preventing increase in the ON voltage of the IGBT, and improving the reverse recovery characteristic of the diode unit by the simpler process.

The present invention is not limited to the above-described embodiment, but includes various modifications. For example, the aforementioned embodiment has been described in detail for easy understanding of the present invention. Therefore, it is not necessarily limited to be configured to have all the structures as described above.

### REFERENCE SIGNS LIST

1: diffusion layer, 2: buffer layer, 3: n-drift layer, 4: insulating layer, 5: emitter electrode/anode electrode, 6: oxide film, 7: Si etch region (second trench), 8: trench, 9: trench (first trench), 10: SBD, 11: pn diode, 12: p body layer, 13: n⁺ layer, 14: p⁺ layer, 15: p layer, 16: p⁺ layer, 17: p layer, 100: semiconductor device, 500: power conversion device, 501 to 506: power switching element, 511 to 516: gate circuit, 521 to 526: diode, 531: P terminal, 532: N terminal, 533: U terminal, 534: V terminal, 535: W terminal

1. A semiconductor device comprising an RC-IGBT having an IGBT unit and a diode unit formed in a single chip, wherein:
the diode unit includes a plurality of first trenches connected to a gate potential or an emitter potential in the absence of a body layer of second conductive type, and a second trench which is formed between two of the first trenches, and connected to the emitter potential; and
a Schottky barrier diode is provided, which is constituted by the second trench and a drift layer of first conductive type in contact with a side wall of the second trench.

2. The semiconductor device according to claim 1, wherein the diode unit includes a first semiconductor layer of second conductive type, which is formed below the second trench, and a second semiconductor layer of second conductive type, which is formed between the first semiconductor layer and the drift layer.

3. A method for manufacturing the semiconductor device according to claim 1, the method comprising the steps of:
forming the first trenches in the diode unit;
forming an Si etch region to be formed as the second trench; and
forming a first semiconductor layer of second conductive type, and a second semiconductor layer of second conductive type by ion implantation and thermal diffusion through the Si etch region.

4. A power conversion device including:
a pair of DC terminals;
AC terminals, the number of which is the same as the number of phases of an AC output;
switching legs, the number of which is the same as the number of phases of the AC output, the switching leg being connected between the pair of DC terminals, and each being made by connecting, in series, two parallel circuits, the parallel circuit being formed of a switching element and a diode connected reversely in parallel to the switching element; and
a gate circuit for controlling the switching element, wherein
the diode and the switching element constitute the semiconductor device according to claim 1.
